(19) United States
(12) Patent Application Publication
(10) Pub. No.: US 2017/0316244 A1
(43) Pub. Date: Nov. 2, 2017

(54) DEVICE FOR ACQUIRING DIGITAL FINGERPRINTS

(71) Applicant: New Imaging Technologies, VERRIERES LE BUISSON (FR)

(72) Inventor: Ni YANG, PALAISEAU (FR)

(21) Appl. No.: 15/520,810

(22) PCT Filed: Oct. 22, 2015
(86) PCT No.: PCT/EP2015/074521

§ 371 Date: Apr. 20, 2017

(30) Foreign Application Priority Data
Oct. 22, 2014 (FR) 1460155

(51) Int. Cl. G06K 9/00; H01L 27/146

(52) U.S. Cl. CPC G06K 9/0002; H01L 27/14678; H01L 27/14643; H01L 27/14612; H01L 27/14625; H01L 27/14636

(57) ABSTRACT

The invention relates to a device for acquiring digital fingerprints which includes an image matrix sensor (1), said sensor being configured such as to acquire at least one image of the digital fingerprints of a finger (2) when said finger (2) is presented to said sensor in the acquisition field thereof, wherein the matrix sensor includes a body made of a semiconducting material (3) in which a matrix of active pixels (4) is formed, the pixels of said matrix of active pixels each including at least one photodiode (5) and being configured such as to operate in solar cell mode.

### TECHNICAL FIELD OF THE INVENTION

The present invention relates to a device for acquiring fingerprints comprising an image array sensor, and more particularly a portable electronic apparatus provided with a device for acquiring fingerprints.

Many portable electronic apparatuses give the possibility of accessing digital resources. This is notably the case of smart mobile telephones of the so called “smartphone” type. Certain of the data of these digital resources are confidential, and their access has to be secured. The first type of access protection historically used for telephones was to require the information of a personal identification number (more known under the acronym of PIN for “personal identification number”) with four numbers. However, this type of protection proved to be easily circumventable, and wieldy to apply by the user, notably because an efficient protection requires that this number be inputted at each session for using the telephone. Thus, other means for securing telephones were explored in order to allow locking and unlocking operations of the telephone which are more ergonomic and simpler. The detection of fingerprints of a user prove to be one of the protection means from among the simpler and the more efficient.

Thus, portable electronic apparatuses provided with a device for acquiring fingerprints have been proposed. These devices comprise a fingerprint sensor which has to be both inexpensive and as less bulky as possible, so as to be able to be incorporated in a mobile apparatus such as a smartphone. Notably, for this application, the fingerprint sensor should be thin, and have low bulkiness. Presently, fingerprint sensors of a small thickness incorporated in telephones mainly use the principle of capacitive detection of fingerprints.

In these sensors, the finger of the user comes into contact with a film at the surface of the sensor, and the differences in materials between an underlying detection electrode and the surface generate a difference in electrical capacitance which may be measured by an active circuit of the sensor. However, capacitive sensors suffer from several limitations for this application. Thus, capacitive sensors are sensitive to electrostatic perturbations. Further, these sensors require a complex and expensive structure, with for example a slide of anisotropic single-crystal sapphire for protecting the sensor while letting through the capacitive variation of the detection surface.

Therefore, another fingerprint sensor using the principle of optical detection was developed. It should be noted that the requirement of a small thickness of the sensors does not allow the use of optical sensors with total internal reflection, or TIR, acronym of “total internal reflection”, for which the optical elements are too bulky.

Patent applications US 2014/036168 and US 2007/252005 have arrays of organic photodiodes in which the same photodiodes are used as a display and for sensing the light. The circuits of the pixels are made with the OLED technologies. These technologies are however not optimal for acquiring images, and the quality of the latter is much less than with the CMOS technology.

Further, these configurations do not give the possibility of making sensors with array of active pixels, wherein each pixel comprises an active amplifier. The photodiodes are then sequentially connected to a common amplifier through a switch. These photodiodes are passive, and do not include any integrated amplifier in the pixels. Thus, the reading of the pixels is made more complex and less efficient than in the case of array of active pixels CMOS.

U.S. Pat. No. 7,366,331 shows an example of an optical sensor of fingerprints with a small thickness. It is proposed there to have a transparent film between a CMOS detection chip and the surface of the finger in order to improve the resulting contrast from the presence or the absence of direct contact with the surface of the detector and the surface of the finger. The illumination with a light source placed in proximity to the detection surface is necessary. In this case, a ring of light-emitting diodes surrounds the detection surface. Patent application US 2006/0102974 also has a similar structure.

Such optical structures are simple and may have low bulkiness, which allows them to be positioned on a portable electronic apparatus such as a smartphone. However, the thereby obtained image of the fingerprints has very low contrast, which limits the reliability thereof.

For fingerprints of a human finger, the contrast between the darkest areas and the brightest areas of the fingerprints is generally less than 20%, or even 10%. When the finger is laid on the detection surface of the fingerprint sensor, a strong light intensity gradient notably appears because of the light source illuminating the finger is placed at the periphery of the sensor and that the ambient light may also itself enter the sensor through the sides of the latter. Thus, there are very strong differences in light intensity detected by the sensor between the centre of the surface of the detector on the one hand, where the central area of contact with the finger is found, which is dark, and on the other hand the areas at the periphery of the surface of the detector, very bright because of the illumination and of ambient light.

Strong disparities in light intensity are detrimental to the efficiency of these sensors. Indeed, either the exposure of the sensor is selected according to the bright areas at the peripheries, or in this case the central area is too dark, or the exposure of the sensor is selected according to the central area, and in this case, the strong luminosity in the peripheral areas saturates the sensor.

FIG. 1 is a diagram illustrating a finger 2 laid on the surface of a transparent film 105 of a sensor 101, and which put in correspondence the curve 102 of the spatial distribution of the light intensity which is measured by the sensor 101. The operating range of the sensor is comprised between both dash lines. It is observed that the light intensity attains both ends of the operating range of the sensor. At the edges of the finger 2, the light intensity attains a maximum 103 corresponding to the upper limit of the sensitivity of the sensor 101, when the sensor 101 arrives at light saturation. The sensor 101 is then no longer capable of restoring the image of the fingerprints, it is dazzled by this too strong intensity. Conversely, at the centre of the finger, the light intensity attains a minimum 104 corresponding to the low limit of the sensitivity of the sensor 101. The sensor 101 is then no longer capable of restoring the image of the fingerprints, it does not give the possibility of distinguishing the latter.

Indeed, by assuming that the image detector CMOS has a detection threshold 1, a standard very good CMOS detector may maintain proper operation until a level 1000 (60 dB of dynamic range). An example of a typical human finger has a fingerprint contrast of 15%. A typical system for recognizing fingerprints may operate with a poor image with a signal-to-noise ratio of at least 5. In this case, the luminance level at the centre of the image should be at least 5/15%=33. In order to avoid the loss of contrast on the edges of the sensor due to saturation of the detector, for which the dynamic range is limited to 1:1000, the edges cannot have a luminance 33 times greater than the central area of the image corresponding to the centre of the finger. Now, it frequently occurs that the illumination conditions are such that the difference is higher.

Indeed, the sensor may notably be used in a sunlit environment. In this case, not only the luminosity may be very strong, but the latter may also have very strong variations. In this situation, the adjustment of the exposure time in a standard sensor becomes very difficult, all the more so because of the requirement of a small thickness, one does not have an optical system provided with a diaphragm which would give the possibility of controlling the exposure of the sensor.

For example, a CMOS sensor generally saturates at a light illumination of less than 10 Lux with an exposure time of 40 ms. During direct exposure to sunlight, the illumination to which is exposed the sensor may easily attain 100 kLux. In this case, the exposure time should be reduced to 4 μs for avoiding saturation of the sensor. When a finger is laid on the sensor, the luminance may drop by a factor 1000 at the centre of the sensor, but remains that of the ambient illumination of the edges of the finger. The sensors used in the state of the art do not give the possibility of meeting such variations in luminance within a sufficiently short time for an interactive use by the user. Systems of the state of the art, such as that of document U.S. Pat. No. 7,366,331, provide a light source for illuminating the finger, in order to reduce the variation in luminance, in order to compensate for the low dynamics of operation of the CMOS sensors with linear rendering. Moreover, the transparent surface film required for the coupling required between the finger and the sensor reduces the contrast of the acquired image and therefore makes the capture and the recognition of the fingerprints more difficult.

### PRESENTATION OF THE INVENTION

The object of the invention is to at least partly find a remedy to these drawbacks and preferentially to all of them, by proposing the use of a logarithmic sensor for acquiring fingerprints. A device for acquiring fingerprints is thereby proposed, comprising an image array sensor, said sensor being configured for acquiring at least one image of the fingerprints of a finger when said finger is presented to said sensor in its acquisition field, wherein the array sensor is a CMOS sensor with active pixels comprising a body in a semi-conducting material on which is made an array of active pixels, the active pixels of said array of active pixels each comprising at least one photodiode and being configured for operating in a solar cell mode, said photodiodes being configured for having a voltage response according to a logarithmic law relatively to the illumination of said pixels.

A logarithmic sensor has the advantage of having a dynamic operating range which is very extended. Absence of saturation may be ensured without any control even in the case of direct exposure to the sun. This great operating dynamics provides instantaneous reactivity for a mobile device.

This device is advantageously completed with the following features, taken alone or in any of their technically possible combinations:
links for allowing transmission of the images acquired by said sensor cross the body in a semi-conducting material of the sensor for connecting a surface of the body of the sensor to a substrate provided with connection tracks;
the body of the sensor comprises an upper face at which is formed the array of active pixels and a lower face in contact with a substrate provided with connection tracks, wherein the upper face of the body of the sensor comprises at least two areas having different levels:
   an upper level at least for an area intended to be facing the finger, and
   a lower level for an area intended to receive links for allowing transmission of the images acquired by said sensor;
the lower level area is covered in the direction of the acquisition field with a protective material;
the sensor is without any over layer covering the array of active pixels, so that when the finger is presented to said sensor, said finger is in contact with the array of active pixels;
the device comprises a platelet of optical fibers positioned at the surface of the array of pixels and consisting of a bundle of optical fibers oriented in the direction of the acquisition field;
the platelet is configured so as to come into contact with the finger when said finger is presented to the sensor;
the device comprises a member sensitive to pressure positioned so as to emit a signal controlling the acquisition of said image when the finger exerts pressure on the device;
the photodiodes of each active pixel of the array are connected through an initialization transistor to a common node, the voltage of which corresponds to the average of the voltages on the terminals of photodiodes of the active pixels when the initialization transistors are conducting;
each active pixel comprises at least two analogue memories in parallel configured for respectively storing in memory the values of a first reading of the photodiode and of a second reading of the photodiode;
each active pixel comprises a digitization circuit for digitizing the reading value of the photodiode.

The invention also relates to a method for acquiring fingerprints by means of a device according to the invention, wherein the photodiodes of the active pixels of the image array sensor operate in a solar cell mode during the acquisition of at least one image of the fingerprints of a finger when said finger is presented to the sensor.

### PRESENTATION OF THE FIGURES

The invention will be better understood, by means of the description hereafter, which relates to embodiments and alternatives according to the present invention, given as non-limiting examples and explained with reference to the appended schematic drawings, wherein:

FIG. 1, having already received comments, illustrates a finger laid at the surface of a sensor, and matches the curve of the spatial distribution of the light intensity which is measured by the sensor;

FIG. 2 is a diagram illustrating a detail of an image array sensor according to a possible embodiment of the invention, on which a finger has been laid;

FIG. 3 illustrates a finger laid at the surface of a sensor according to a possible embodiment of the invention, and matches the curve of the spatial distribution of the light intensity which is measured by the sensor;

FIG. 4 illustrates an example of a structure of an active pixel for a photodiode in a logarithmic mode;

FIG. 5 illustrates a schematic example of an array of active pixels with a common initialization node;

FIG. 6a is a time diagram schematically illustrating the double reading of active pixels of the array of FIG. 5 and FIG. 6b shows the reading levels obtained following the double reading of FIG. 6a;

FIG. 7 schematically illustrates a structure of an active pixel incorporating analogue memories;

FIG. 8 schematically illustrates a structure of an active pixel incorporating a digitization circuit;

FIG. 9 is a time diagram schematically illustrating the operation of the active pixel of FIG. 8;

FIGS. 10 to 13 are diagrams illustrating different types of devices for acquiring fingerprints according to possible embodiments of the invention.

On the whole of the figures, similar elements are designated with the same references.

### DETAILED DESCRIPTION

With reference to FIG. 2, the device for acquiring fingerprints comprises an image array sensor 1 which is configured for acquiring at least one image of the fingerprints of a finger 2 when said finger 2 is presented to said sensor in its acquisition field. The array sensor 1 comprises a body in a semi-conducting material 3 on which is made an array of active pixels 4.

The sensor 1 is a logarithmic sensor. The pixels of the array of active pixels 4 each comprise at least one photodiode 5 and are configured for operating in a solar cell mode. Thus, the photodiodes 5 are configured for exhibiting a voltage response following a logarithmic law relatively to the illumination of said pixels. Typically, the image array sensor 1 is a CMOS sensor. Metal interconnections 6 ensure electrical connections between the photodiodes 5. These metal interconnections 6 are illustrated here in a configuration in which they are in front of the photodiodes 5, i.e. in their acquisition field, between the finger 2 and said photodiodes 5. However it is possible to use a so called illumination configuration from the backside (“back side illumination”), wherein metal interconnections are behind the photodiodes relatively to the acquisition field of the latter, with therefore the photodiodes located between the metal interconnections and the finger.

The image array sensor 1 is adapted for acquiring an image of the surface of a finger laid on its surface. Thus, in the example of FIG. 2, a finger 2 is laid at the surface of the sensor 1, i.e. at the surface of the array 4. The skin at the surface of a finger has crests 21 and papillary grooves 22 forming a dermatoglyph, commonly designated as a fingerprint, by association with the trace left by said dermatoglyph. While a crest 21 actually touches the surface of the array 4, some air is present between a papillary groove 22 and said surface. These differences in configurations are expressed in an image acquired by the acquisition device with different contrasts, which take into account fingerprints of the finger 2.

The acquired image should therefore restore the contrast of the finger positioned in the acquisition field of the sensor. With a device of the state of the art, for which the sensor produces a response proportional to the light intensity in its acquisition field, the resulting contrast depends on the absolute luminance received by the sensor. On the other hand, with a logarithmic sensor like in the scope of the invention, the contrast is restored independently of the absolute luminance. Indeed, the great operating dynamics of the logarithmic sensor gives the possibility of removing the saturations, and the contrast may then be determined according to a relative luminance, in the absence of a saturation threshold forming absolute threshold. The result of this is that the image of the fingerprint may be acquired with constant quality regardless of the illumination conditions, and notably in spite of the differences in luminance between the edges of the finger and the centre.

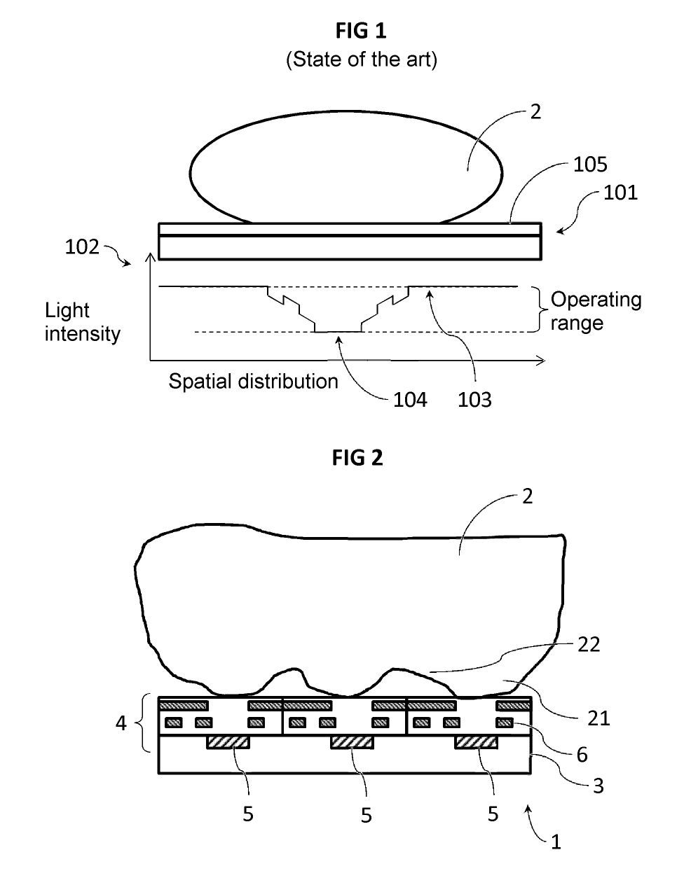

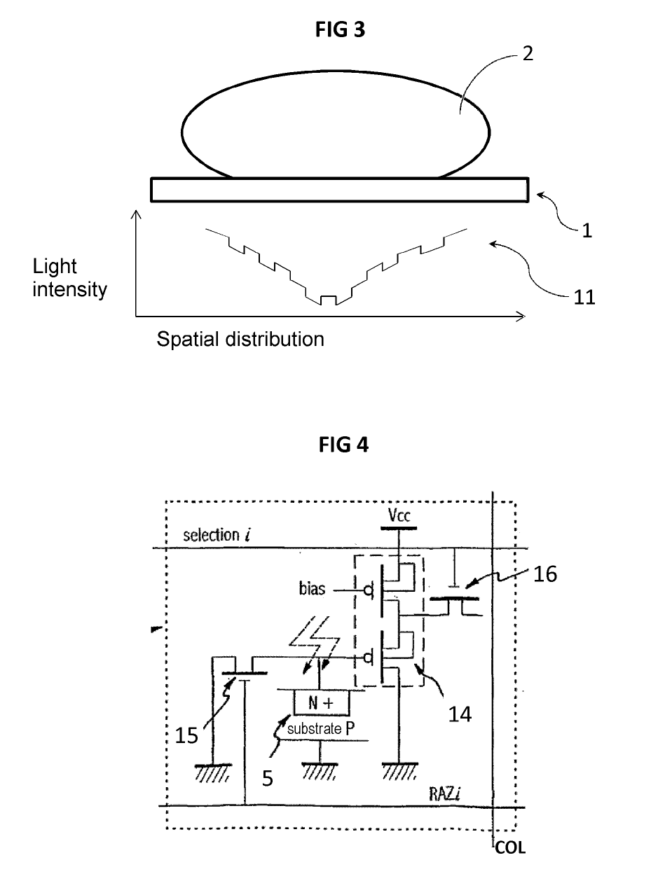

FIG. 3 is a diagram illustrating a finger 2 laid on the surface of a sensor 1, and which matches the curve 11 of the spatial distribution of the light intensity which is measured by the sensor 1. By comparison with FIG. 1, it is seen that the variations of light intensity, i.e. the contrast, are retained in spite of the large differences in light intensities according to the areas of the sensor 1, by the absence of saturation of the latter.

In the field of standard CMOS technology, a photodiode is generally formed with a PN junction with an N diffusion in a substrate of type P. During operation in a solar cell mode, this photodiode generates a negative voltage in an open circuit, the absolute value of which is proportional to the logarithm of the illumination level of the photodiode.

During the exposure, the photodiode is completely discharged and the voltage on the photodiode is then negative:

$${V}_{PD} = - \frac{kT}{q} ln ( \frac{{I}_{λ}}{{I}_{s}} + 1 ) < 0$$

wherein k is the Boltzmann constant, q is the elementary charge, T is the absolute operating temperature of the photodiode and Iₛ represents a reverse current also called a saturation current of the junction of the photodiode, observed when a diode is reverse-biased in the total absence of light. The voltage on the photodiode is then proportional to the logarithm of the light intensity. It is said in this case that the photodiode operates in a logarithmic area.

The photodiodes 5 are configured for operating in a solar cell mode, i.e. for having a voltage response according to a logarithmic law relatively to the illumination of the pixels, for example with zero or a direct bias.

In an array of active pixels of an image array sensor, each pixel contains a photodiode and an active amplifier. An example of an active pixel structure is illustrated with FIG. 4. The PN junction forming the photodiode 5 consists of a semi-conducting substrate of type P on which a diffusion of type N is carried out. A switch 15 of the photoelectric element is controlled by a control line for resetting to zero (RAZ). A selection switch 16 allows selection of the outlet of the circuit for its reading. The switch 15 as well as the switch 16 are formed with field effect transistors MOS with a N channel. Finally, an active amplifier 14 is made with two MOS field effect transistors with a channel P in series, powered by a power supply voltage VCC, the first transistor being connected to a biasing voltage giving the possibility of adjusting the additional voltage gain which is intended to be provided to the output voltage Vs. This voltage Vs is connected to the second MOS field effect transistor with a channel P of the amplifier, and then delivered on the reading bus COL.

The output voltage Vs of the photodiode 5 is read by the active amplifier 14, which has an infinite input impedance in DC current. As the photodiodes 5 are configured for operating in a solar cell mode, the active amplifier 14 is capable of reading the negative voltage delivered by the photodiode 5.

Other circuits which may be used are described in documents EP1354360, EP2186318 or further WO 2010/103464. The reading of the whole of the pixels of the array gives the possibility of obtaining the acquired image.

For a device for acquiring fingerprints, it is preferable to obtain an image centered on an average value common to the photodiodes. This notably gives the possibility of facilitating the binarization of the image, i.e. the classification of the pixels of the image relatively to a threshold, in this case this average value.

FIG. 5 illustrates an example of such an embodiment, showing for reasons of only simplification two schematized active pixels of an array. The initialization transistors 15, controlled by the initialization signal RST, are connected to a floating common node 17, the voltage of which is determined by reading the pixels of the array. More specifically, this common node 17 corresponds to the putting into common the outputs of each pixel, and its voltage is therefore the average value of the outputs of the pixels.

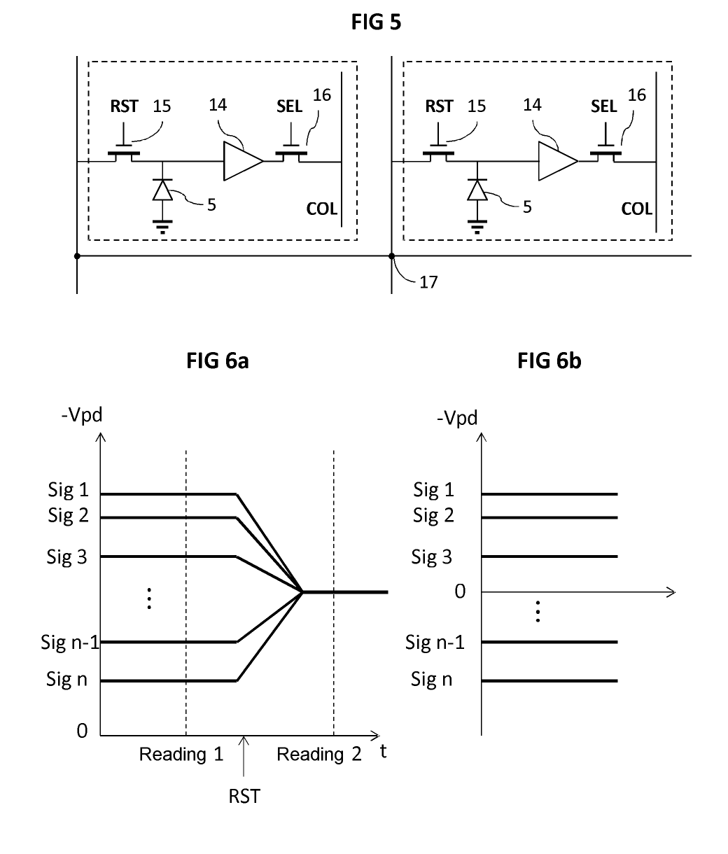

With reference to the time diagram of FIG. 6a, a first reading (reading 1) is first carried out, allows recovery, on each active pixel, via the COL bus, the measured value of its exposure. The output signals of the different pixels are noted as Sig1, Sig 2, Sig 3 etc. The values of this first reading correspond to the acquired image. And then, the initialization signal RST, maintained, controls the initialization transistors 15 in a conducting condition, connecting the whole of the active pixels to the common node 17. The voltage of the common node 17 resulting from this corresponds to the average value of the first readings.

A second reading is then carried out (reading 2) when the initialization signal RST is activated and the pixels are connected to the common node 17. This second reading gives the average value. FIG. 6b shows the result of the differential reading, when the difference between the first reading and the second reading (reading 1−reading 2) is determined. It is then seen that the different final values of the signals Sig are from now on centered around a fixed value which corresponds to the average of the signals, and which by the differential reading is zero. It is then easy to assign a symbol, for example “1”, to the signals above zero and another symbol, for example “0”, to signals below zero. A binary image is thereby easily obtained.

Typically, the readings are accomplished line per line. In order to make this operation more efficient, it is possible to provide the putting of at least two analogue memories in each pixel so as to be able to perform readings in parallel. The first memory is filled by the first reading before the initialization, and the second memory is filled with the second reading during activation of the initialization signal RST.

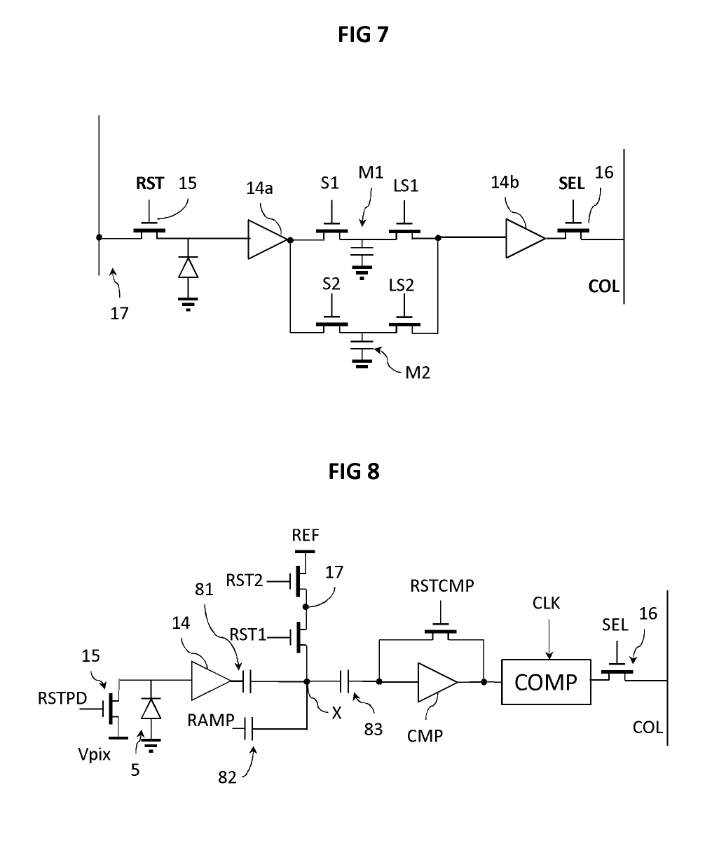

FIG. 7 shows a possible exemplary embodiment of this configuration. The structure of the pixel is similar to the one shown earlier, except for the presence of two parallel branches between a first amplifier 14a and a second amplifier 14b. Each branch comprises a capacitor M1, M2 connected to the ground and to the common electrode of both transistors in series, including a transistor S1, S2 which is connected to the first amplifier 14a in order to control the reading in memory and the other transistor LS1, LS2 is connected to the second amplifier 14b for controlling the reading of the memories. With the controls of the transistors S1, S2, LS1, LS2, it is possible to carry out parallel readings of the pixels with a traditional circuit reading the COL bus.

Generally, the size of the pixels for a device for acquiring fingerprints is relatively large. For example, the FBI standard imposes a pixel size of 50 μm. This size gives the possibility of integrating many more transistors than required for amplification and reading. It is then possible to integrate a digitization circuit in each active pixel of the array. The output of the active pixel on the COL bus is then a determined digital value from the analogue value of the reading.

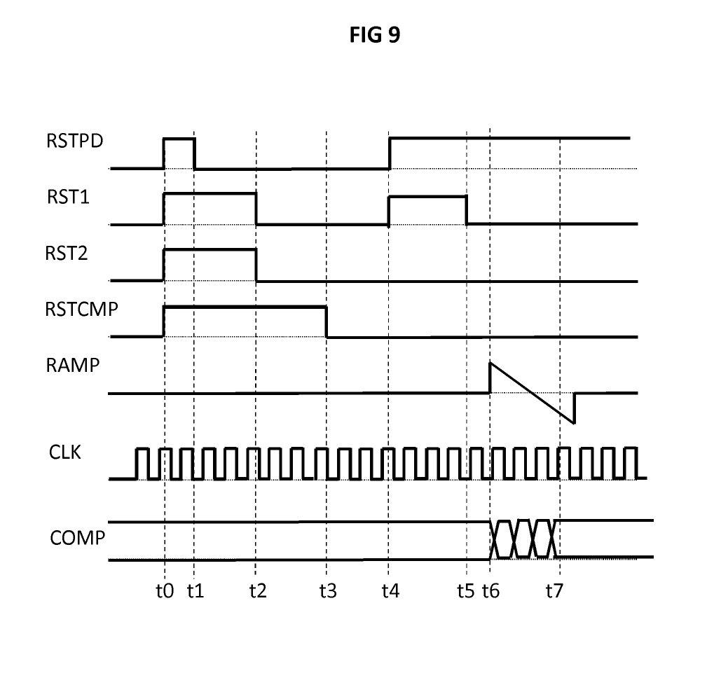

An exemplary embodiment is illustrated in FIG. 8. In the pixel, the photodiode 5 is again found as well as the initialization transistor 15 controlled by an RSTPD signal. The initialization transistor connects the photodiode to an initialization voltage Vpix, typically comprised between 0 and 0.5 V. The initialization voltage Vpix is preferably slightly positive, for example greater than 0.1 V, such as 0.3 V, in order to have better sensitivity.

Downstream from the active amplifier 14 to which is connected the photodiode 5 is found a capacitor 81 connected to a node X. Another capacitor 82 is connected on one hand to a RAMP voltage and on the other hand to the node X. The node X is also connected to two transistors in series respectively controlled by the signals RST1 and RST2, and their common electrode forms the common node 17. Finally, at the node X is connected a terminal of a capacitor 83. The other terminal of the capacitor 83 is connected to a comparator CMP in parallel with a transistor controlled by the RSTCMP signal. Downstream from the comparator CMP is found a binary counter COMP to which is provided a clock CLK. The output of the binary counter COMP is connected to the COL bus through the selection transistor 16 controlled by the SEL signal.

FIG. 9 shows the operation of such a pixel structure. The time diagram begins during the exposure. In a first phase t1, the photodiode 5 is reset by means of the RSTPD signal controlling the conducting condition of the initialization transistor 15. The signals RST1 and RST2 make their respective transistors conducting, thus maintaining the node X at the reference voltage REF. The RSTCMP signal also makes the transistor parallel to the comparator CMP conducting, resetting the latter. And then at t2, at the end of the exposure, the node X is made floating by deactivation of the signals RST1 and RST2, the transistors of which are then made to be blocked. Next at t3, the RSTCMP signal is disabled, making the transistor parallel to the comparator CMP non-conducting, making the latter operational.

The RSTPD signal is again activated at t4, making the initialization transistor 15 conducting. The variation of voltage at the terminals of the photodiode 5 then propagates to the node X, forming the image signal.

Subsequently at t5, the RST1 signal is activated, while the signal RST2 remains disabled. The common node 17 is then connected to the node X. The average value of the image is therefore obtained on the node X. Let us recall that the common node 17 is common to the whole of the pixels. The node X is surrounded by capacitors 81, 82, 83, only the variations in voltage may be propagated thereto. Consequently, on the input of the comparator CMP is again found the variation of the voltage on the node X corresponding to the difference between the image signal and the average.

The digitization is accomplished with activation of the RAMP signal and of the binary counter COMP. The RAMP signal is a signal which decreases over time, covering the possible values of the image signal. The counter COMP is controlled by the output of the comparator CMP. The counter COMP counts the number of clock signals from the clock CLK as long as its input, i.e. the output of the comparator CMP, is not modified. The comparator CMP compares its input with a threshold level, typically zero. The comparator CMP switches at t7 when the level of the RAMP signal joins up with the difference between the image signal and the average.

Depending on the difference between the pixel signal and the average of the outputs of the pixels present on the common node 17, the application of the RAMP signal will take more or less time to join up the difference between the image signal and the average. Thus, the counting stops more or less earlier, the result of this is that the number of clock signals counted before the switching of the output of the comparator CMP is a digital representation of the difference between the image signal and the average.

As earlier, the reading is accomplished via the selection transistor 16 controlled by the selection signal SEL connecting the counter COMP to the COL bus, except for the fact that this is no longer here an analogue signal but a digital signal coding the value of the reading of the pixel.

It is also possible to replace the counter COMP in each pixel with a single counter common to all the pixels. In this case, a plurality of gates of transistors in parallel is connected to the output of the comparator CMP, each transistor connecting a capacitor to a binary output of the COMP counter. During the switching of the comparator CMP, the pixel then directly stores in its capacitors the binary coding corresponding to its image value.

Several configurations of sensors including photoelectric elements, for which the photoelectric conversion verifies a logarithmic law are possible. In the illustrated examples, the array sensor is mounted on a substrate provided with connection tracks, and the array of active pixels is connected to these connection tracks in order to allow transmission of the images acquired by said sensor.

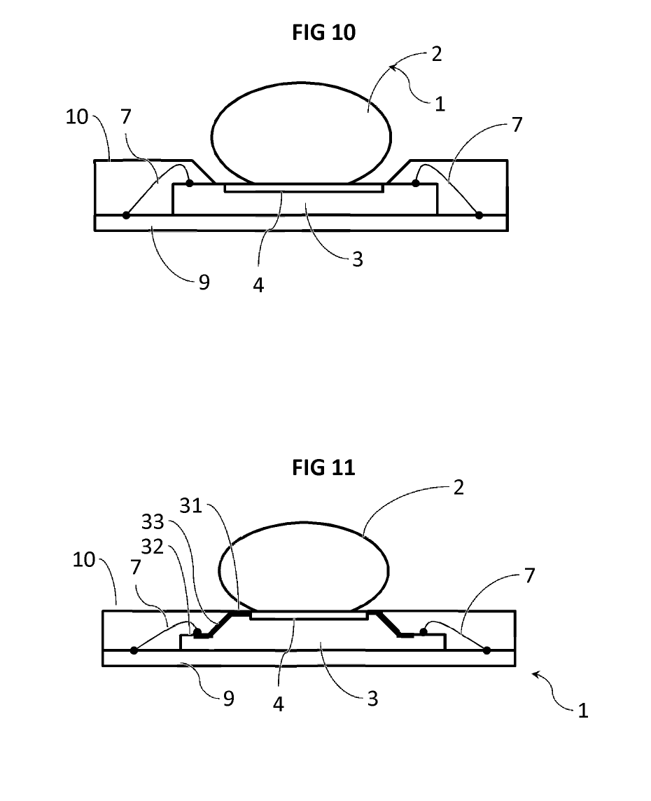

In the example of FIG. 10, the body of the sensor has a parallelepiped shape, with an upper face at which is formed the array of active pixels 4 and a lower face in contact with the substrate 9 which are both planar and parallel. Connection wires 7 connect the upper surface of the semi-conducting body 3 to the connection tracks of the substrate 9, in order to electrically connect the array of active pixels 4 to these tracks. These connection wires 7 are embedded in a protective layer 10, typically in polymeric resin.

FIG. 11 illustrates an improvement in the configuration of FIG. 10, which gives the possibility notably of producing a device with a thinner thickness. The upper face of the body 3 of the sensor comprises at least two areas 31, 32 having different levels relatively to the substrate 9: an upper level at least for an area 31 intended to be in contact with the finger 2, and a lower level for an area 32 intended to receive links 7 in order to allow transmission of the images acquired by said sensor. The lower level area 32 therefore corresponds to a lesser thickness of the body 3 relatively to that of the area 31 of an upper level. The upper level area 31 therefore has a height relatively to the substrate 9 greater than that of the lower level area 32.

Conductive tracks 33 at the surface of the lower level area 32 connect the connection tracks of the array 4 to the links 7, said links 7 connecting said conductive tracks 33 to the connection tracks of the substrate 9. The lower level area 32 is covered in the direction of the acquisition field with a protective material 10, typically in polymeric resin, and the links 7 are embedded in said protective layer 10, while the upper level area 31 is left free by the protective layer 10.

Such a structure has a lesser thickness than that of FIG. 10, since the over-thicknesses required for the connection wires 7 then are not expressed by an over-thickness of the protective layer 10 relatively to the level of the array of active pixels 4, which then forms the maximum height of the device.

In order to obtain such a structure, it is possible to apply dry or humid etching of the body 3 around the array of active pixels 4. Electric conduction tracks 33 are then deposited by selective electro-plating at the surface of the lower level area 32, in order to extend the connection tracks of the array 4 as far as the lower level area 32. The links 7 are then set into place conventionally for connecting said conductive tracks 33 to the connection tracks of the substrate 9.

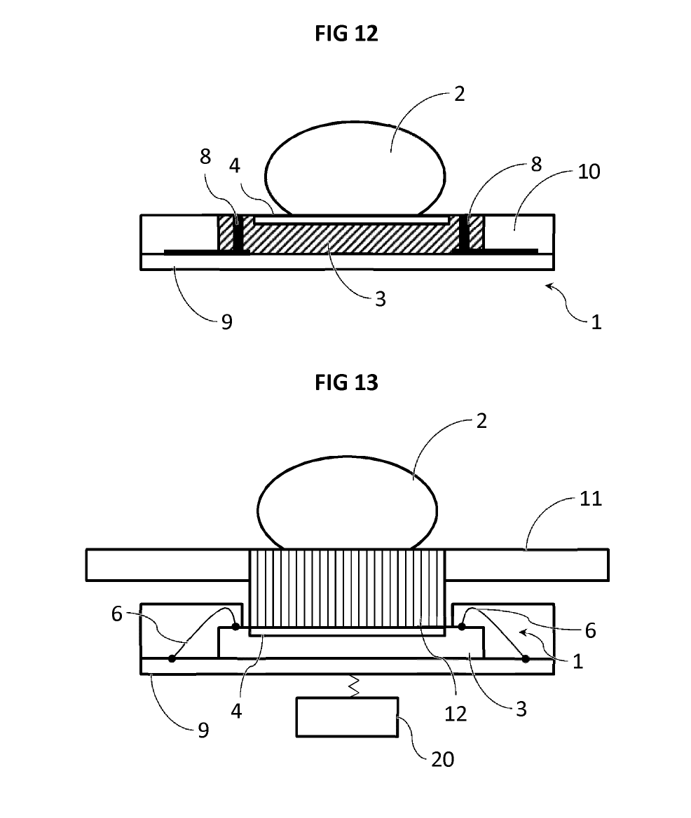

FIG. 12 illustrates another configuration, in which the body 3 in a semi-conducting material of the sensor is crossed by links 8 for connecting a surface of the body 3 of the sensor to the connection tracks of the substrate 9. This type of link 8 is known by the acronym TSV, “through silicon via”. Although in the illustrated example, the links 8 are perpendicular to the surface of the substrate 9 and to the surface of the body 3 of the sensor 1, other orientations are however possible. This configuration gives the possibility of obtaining a flat surface, whether this is for the body 3 of the sensor or for the protective layer 10, which rises on the edges of the body 3, at the same level as the latter.

In these different embodiments, the sensor 1 may be without any over layer covering the array of active pixels 4, so that when the finger 2 is presented to said sensor, said finger 2 is in contact with the array of active pixels 4. The absence of an over layer simplifies the manufacturing, reduces the cost, and gives the possibility of not adding over-thickness to the sensor 1. A protective over layer as a transparent film may however be provided at the surface of the sensor for protecting the latter. Nevertheless, this over layer does not have to have particular characteristics in electric terms, as this is the case for the capacitive sensors.

FIG. 13 has another configuration, wherein the sensor 1 is mounted on the substrate in a similar way to that of FIG. 10, but which may just as well be that of FIG. 11 or 12. An optical fiber platelet 12 is positioned at the surface of the sensor 1, so as to conduct the light from the reception area of the finger as far as the array of active pixels 4. The optical fiber platelet 12 consists of a bundle of optical fibers oriented towards the acquisition field. The optical fibers of the platelet 12 are therefore oriented in the direction connecting a detection surface for receiving the finger to the array of active pixels 4. The platelet 12 is configured for coming into contact with the finger 2 when said finger is presented to the sensor. The optical fiber platelet 12 may be crimped in an embellishment part 11 useful concealing to the user the underlying elements. This configuration provides excellent protection to the sensor 1, and gives the possibility of obtaining a detection surface for receiving the finger which is flat and smooth.

In all the embodiments, the device for acquiring fingerprints may comprise a pressure-sensitive member positioned so as to emit a signal controlling the acquisition of the image when the finger exerts pressure on the device. The pressure-sensitive member may for example be an electromechanical switch or else a pressure sensor measuring pressure. FIG. 13 thus shows a pressure-sensitive member 20 under the substrate 9, configured for detecting the pressure exerted by a finger 2 on the sensor, and controlling the acquisition of an image by the sensor.

A device for acquiring fingerprints as described herein is preferably incorporated to a portable electronic apparatus such as a smartphone, in order to acquire the fingerprints of a user of the electronic apparatus.

The invention is not limited to the described embodiment and illustrated in the appended figures. Modifications remain possible, notably from the point of view of the constitution of the diverse elements or by substitution of technical equivalents, without however departing from the protection field of the invention.

1. A device for acquiring fingerprints comprising an image array sensor (1), said sensor being configured for acquiring at least one image of the fingerprints of a finger (2) when said finger (2) is presented to said sensor in its acquisition field,
characterized in that the array sensor is a CMOS sensor with active pixels comprising a body in a semi-conducting material (3) on which is made an array of active pixels (4), the active pixels of said array of active pixels each comprising at least one photodiode (5) and being configured for operating in a solar cell mode, said photodiodes (5) being configured for having a voltage response according to a logarithmic law relatively to the illumination of said pixels.

2. The device according to the preceding claim, wherein links (8) for allowing transmission of the images acquired by said sensor cross the body (3) in a semi-conducting material of the sensor for connecting a surface of the body of the sensor to a substrate (9) provided with connection tracks.

3. The device according to claim 1, wherein the body (3) of the sensor comprises an upper face at which is formed the array of active pixels (4) and a lower face in contact with a substrate (9) provided with connection tracks, wherein the upper face of the body (3) of the sensor comprises at least two areas (31, 32) having different levels:
an upper level at least for an area (31) intended to be facing the finger (2), and
a lower level for an area (32) intended to receive links (7) for allowing transmission of the images acquired by said sensor.

4. The device according to the preceding claim, wherein the lower level area (32) is covered in the direction of the acquisition field with a protective material (10).

5. The device according to one of the preceding claims, wherein the sensor (1) is without any over layer covering the array of active pixels (4), so that when the finger (2) is presented to said sensor, said finger (2) is in contact with the array of active pixels (4).

6. The device according to one of claims 1 to 4, wherein the device comprises a platelet of optical fibers (12) positioned at the surface of the array of pixels and consisting of a bundle of optical fibers oriented in the direction of the acquisition field.

7. The device according to the preceding claim, wherein the platelet (12) is configured for coming into contact with the finger (2) when said finger is presented to the sensor.

8. The device according to any one of the preceding claims, comprising a pressure-sensitive member (20) positioned so as to emit a signal controlling the acquisition of said image when the finger exerts pressure on the device.

9. The device according to any one of the preceding claims, wherein the photodiodes of each active pixel of the array are connected through an initialization transistor (15) to a common node (17), the voltage of which corresponds to the average of the voltages on the terminals of photodiodes of the active pixels when the initialization transistors are conducting.

10. The device according to the preceding claim, wherein each active pixel comprises at least two analogue memories in parallel configured for respectively storing in memory the values of a first reading of the photodiode and of a second reading of the photodiode.

11. The device according to one of the preceding claims, wherein each active pixel comprises a digitization circuit for digitizing the reading value of the photodiode.

12. A portable electronic apparatus provided with a device for acquiring fingerprints according to any one of the preceding claims.

13. A method for acquiring fingerprints by means of a device according to one of claims 1 to 11, wherein the photodiodes of the active pixels of the image array sensor operate in a solar cell mode during the acquisition of at least one image of the fingerprints of a finger when said finger is presented to the sensor.
